(19) United States
(12) Patent Application Publication
(10) Pub. No.: US 2009/0302897 A1
(43) Pub. Date: Dec. 10, 2009

(54) Driver circuit having high reliability and performance and semiconductor memory device including the same

(75) Inventors: Jin-Young Kim, Seoul (KR); Ki-Whan Song, Yogin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/457,240

(22) Filed: Jun. 4, 2009

(30) Foreign Application Priority Data
Jun. 5, 2008 (KR) 10-2008-0053217

(51) Int. Cl. H03K 3/00

(52) U.S. Cl. 327/108

(57) ABSTRACT

Example embodiments relate to a driver circuit and a semiconductor memory device including the driver circuit. The driver circuit includes a pull-up unit configured to connect an output node to a first power supply voltage in response to an input signal, an interface unit connected between the output node and a first node to decrease a voltage of the output node in response to a control signal, and a pull-down unit configured to connect the first node to a second power supply voltage. The interface unit includes a first transistor configured to connect the output node with the first node in response to the control signal and a first resistor connected between the output node and the first node. The interface unit may also include a second resistor and a second transistor connected in series between the output node and the first node.

### FOREIGN PRIORITY STATEMENT

This application claims priority under 35 U.S.C. §119 to Korean Patent Application No. 10-2008-0053217, filed on Jun. 5, 2008, in the Korean Intellectual Property Office (KIPO), the entire contents of which are incorporated herein by reference.

### BACKGROUND

1. Field

Example embodiments relate to a semiconductor memory device, for example, a driver circuit having high reliability and performance and a semiconductor memory device including the driver circuit.

2. Description of the Related Art

Although a single power supply is used for semiconductor memory devices, a semiconductor memory device, such as dynamic random access memory (DRAM), requires multi-level voltages in order to drive a plurality of circuits implemented therein. The semiconductor memory device may utilize a driver circuit to generate a voltage higher or lower than an input signal and may drive internal circuits using the generated voltage. For instance, when the driver circuit is a row driver circuit, the driver circuit may receive and amplify a row address signal decoded by a row decoder to activate at least one word line among a plurality of word lines in the semiconductor memory device.

However, conventional driver circuits may not output a reliable voltage due to the characteristics of circuit elements constituting the driver circuits. For instance, when a driver circuit is an inverter circuit having a structure wherein a P-type metal-oxide semiconductor (PMOS) transistor and an N-type metal-oxide semiconductor (NMOS) transistor are connected in series, an output voltage may be unstable due to the operational characteristics (e.g., an increase of a drain-source voltage) of the NMOS transistor.

### SUMMARY

According to an example embodiment a driver circuit may include a pull-up unit, an interface unit and a pull-down unit. The pull-up unit is configured to connect an output node to a first power supply voltage in response to an input signal. The interface unit is connected between the output node and a first node and is configured to decrease a voltage of the output node in response to a control signal. The pull-down unit is configured to connect the first node with a second power supply voltage. The interface unit includes a first transistor configured to connect the output node with the first node in response to the control signal and a first resistor connected between the output node and the first node. A voltage level of the control signal may be equal to a level of the first power supply voltage.

According to an example embodiment, the pull-up unit may be a p-type metal-oxide semiconductor (PMOS) transistor and the pull-down unit may be an n-type metal-oxide semiconductor (NMOS) transistor.

According to an example embodiment, the interface unit may further include a second resistor and a second transistor connected in series with each other between the output node and the first node of the driver circuit.

The channel width and the channel length of the first transistor may be equal to the channel width and channel length of the second transistor, respectively.

According to an example embodiment, the layout of the driver circuit may include the first and second resistor implemented using a common resistor.

According to an example embodiment, a semiconductor memory device may include a row decoder, row driver and a sub-word line driver. The row decoder is configured to receive and decode a row address signal and to output a decoded row address signal. The row driver is configured to activate a corresponding word line from a plurality of word lines in response to the decoded signal. The corresponding word line may is connected to an output node of the row driver. The sub-word line driver is configured to activate a corresponding sub-word line from a plurality of sub-word lines in response to a signal input using the activated word line.

The row driver includes a pull-up unit configured to connect an output node to a first power supply voltage in response to the decoded signal, an interface unit connected between the output node and a first node to decrease a voltage of the output node in response to a control signal, and a pull-down unit configured to connect the first node with a second power supply voltage. The interface unit includes a first transistor configured to connect the output node with the first node in response to the control signal and a first resistor connected between the output node and the first node.

A voltage level of the control signal may be equal to a level of the first power supply voltage. The pull-up unit may be a PMOS transistor and the pull-down unit may be an NMOS transistor.

### BRIEF DESCRIPTION OF THE DRAWINGS

The above and other features and advantages of example embodiments will become more apparent by describing in detail an example embodiment with reference to the attached drawings. The accompanying drawings are intended to depict an example embodiment and should not be interpreted to limit the intended scope of the claims. The accompanying drawings are not to be considered as drawn to scale unless explicitly noted.

FIG. 1A is a circuit diagram and FIG. 1B is a layout diagram of a driver circuit according to conventional art;

FIG. 2A is a circuit diagram and FIG. 2B is a layout diagram of a driver circuit according to conventional art;

FIG. 3 is a circuit diagram of a driver circuit according to an example embodiment;

FIG. 4A is a circuit diagram and FIG. 4B is a layout diagram of a driver circuit according to another example embodiment;

FIG. 5A is a graph illustrates an output voltage of a driver circuit according to an example embodiment;

FIG. 5B is a graph illustrating equivalent resistance according to an example embodiment; and

FIG. 6 is a block diagram of a semiconductor memory device according to an example embodiment.

### DESCRIPTION OF EXAMPLE EMBODIMENTS

Detailed example embodiments are disclosed herein. However, specific structural and functional details disclosed herein are merely representative for purposes of describing example embodiments. Example embodiments may, however, be embodied in many alternate forms and should not be construed as limited to only the embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but to the contrary, example embodiments are to cover all modifications, equivalents, and alternatives falling within the scope of example embodiments. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

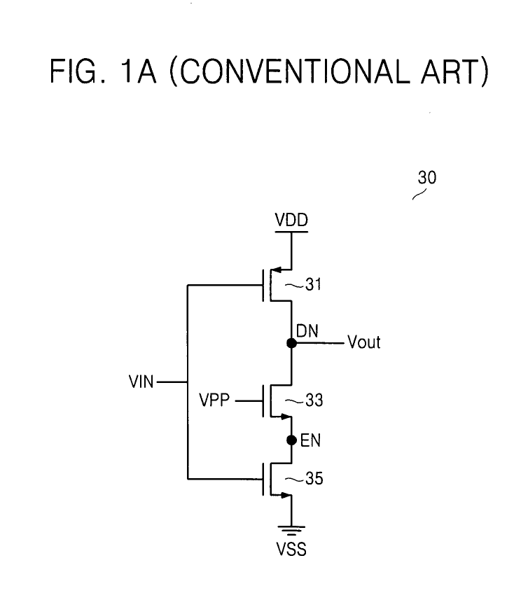

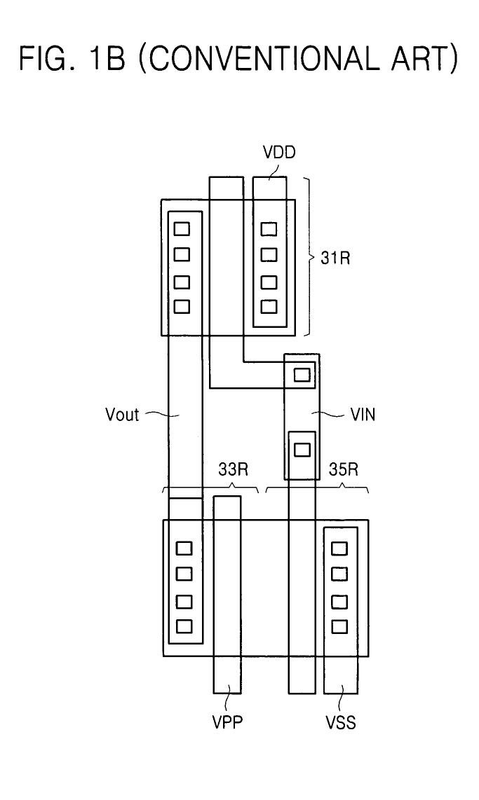

FIGS. 1A and 1B are a circuit diagram and a layout diagram of a driver circuit 30 according to conventional art. Referring to FIGS. 1A and 1B, the driver circuit 30, may be used in a word line driver circuit or a level shift circuit of a semiconductor memory device and may drive an output node DN to a first power supply voltage VDD or a second power supply voltage VSS in response to an input signal VIN. For instance, when the driver circuit 30 is implemented as a word line driver circuit of a semiconductor memory device, the driver circuit 30 may output a driving signal that drives a corresponding sub-word line among a plurality of sub-word lines in response to a decoded signal (or an input signal) received from a word line decoder.

The driver circuit 30 may include a first transistor 31, a second transistor 33, and a third transistor 35. The first transistor 31 may be connected between the first power supply voltage VDD and the output node DN and gated in response to the input signal VIN, thereby forming a current path between the first power supply voltage VDD and the output node DN. The second transistor 33 may be connected between the output node DN and a first node EN and gated in response to the input signal VPP, thereby forming a current path between the output node DN and the first node EN. The third transistor 35 may be connected between the first node EN and a second power supply voltage VSS and gated in response to the input signal VIN, thereby forming a current path between the first node EN and the second power supply voltage VSS.

Referring to FIG. 1B, the first transistor 31, the second transistor 33, and the third transistor 35 may be disposed in a first region 31R, a second region 33R, and a third region 35R, respectively.

In the conventional art illustrated in FIGS. 1A and 1B, a voltage difference between the first node EN (drain terminal) and the second power supply voltage VSS (source terminal) of the third transistor 35 may decrease due to the presence of the second transistor 33 between the first transistor 31 and the third transistor 35. This decrease in the drain-source voltage may increase the reliability of the third transistor 35. In other words, degradation of the third transistor 35 over time may slow down due to decrease in voltage difference between the drain and the source of the third transistor 35.

However, the reliability of the second transistor 33 may be poor, since the drain-source voltage of the second transistor 33 may be greater than the drain-source voltage of the third transistor 35. Degradation may be reduced by decreasing the drain-source voltage of the second transistor 33 using the following example methods.

First, a channel length of the second transistor 33 may be reduced in order to decrease the drain-source voltage of the second transistor 33. However, this may cause the reliability to increasingly deteriorate as a result of the unique transistor characteristic.

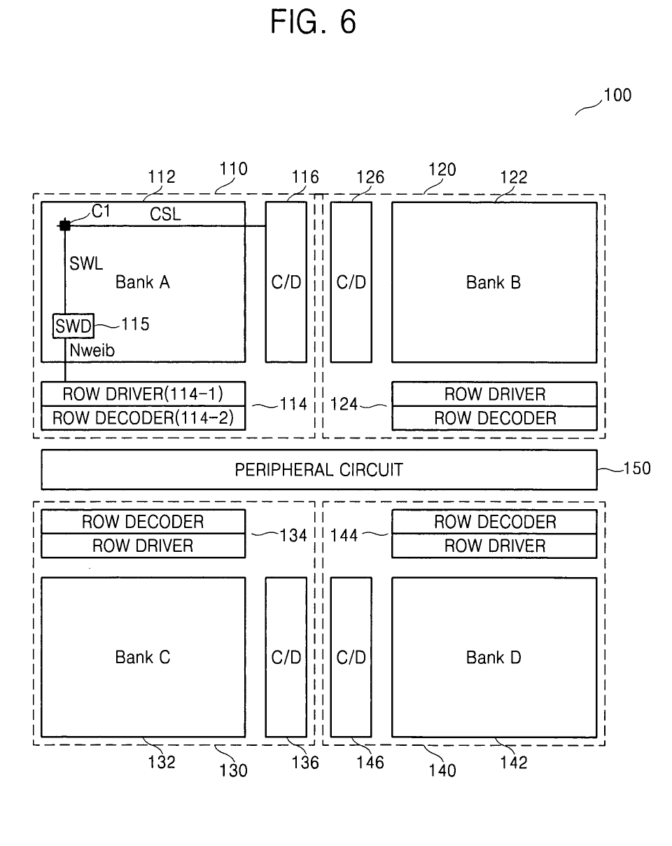

Second, a channel width of the second transistor 33 may be increased in order to decrease the drain-source voltage of the second transistor 33. However, this may cause an increase in an area of a circuit or a system where the second transistor 33 is implemented. For instance, when the second transistor 33 is implemented in a row decoder (e.g., 114, 124, 134, or 144 in FIG. 6) of a DRAM (e.g., 100 in FIG. 6), the area occupied by the row decoder may increase. Therefore, a driver circuit having high reliability and high performance without decreasing the channel length of the second transistor 33 and/or increasing the channel width of the second transistor 33 is desirable.

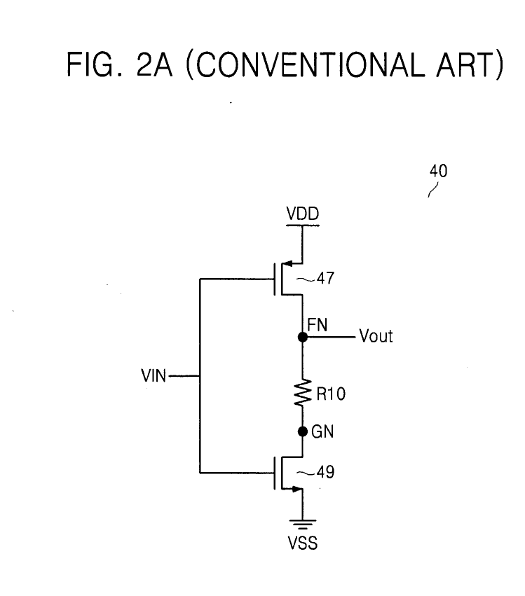

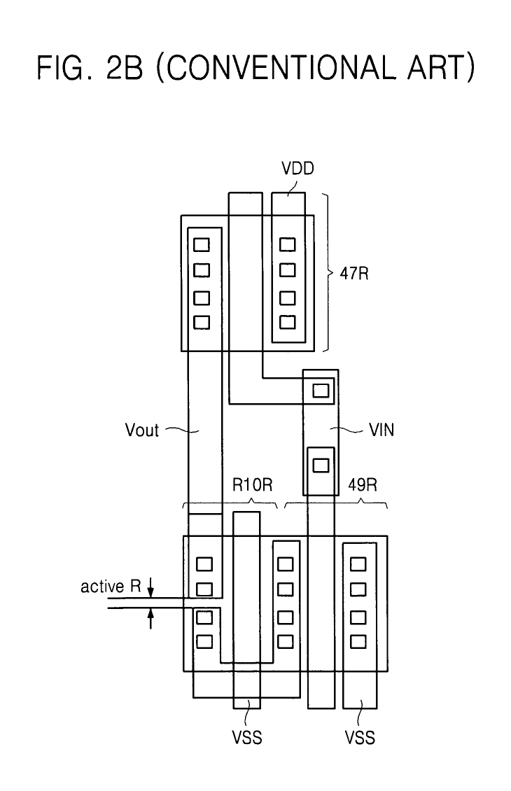

FIGS. 2A and 2B are a circuit diagram and a layout diagram of a driver circuit 40 according to conventional art. Referring to FIGS. 2A and 2B, the driver circuit 40, which may be used in a word line driver circuit or a level shift circuit of a semiconductor memory device, may drive an output node FN to a first power supply voltage VDD or to a second power supply voltage VSS in response to an input signal VIN.

The driver circuit 40 may include a first transistor 47, a resistor R10, and a second transistor 49. The first transistor 47 may be connected between the first power supply voltage VDD and the output node FN and may be gated in response to the input signal VIN, thereby forming a current path between the first power supply voltage VDD and the output node FN. The resistor R10 may be connected between the output node FN and a first node GN. The second transistor 49 may be connected between the first node GN and the second power supply voltage VSS and gated in response to the input signal VIN, thereby forming a current path between the first node GN and the second power supply voltage VSS.

Referring to FIG. 2B, the first transistor 47, the resistor R10, and the second transistor 49 may be disposed in a first region 47R, a second region R10R, and a third region 49R, respectively.

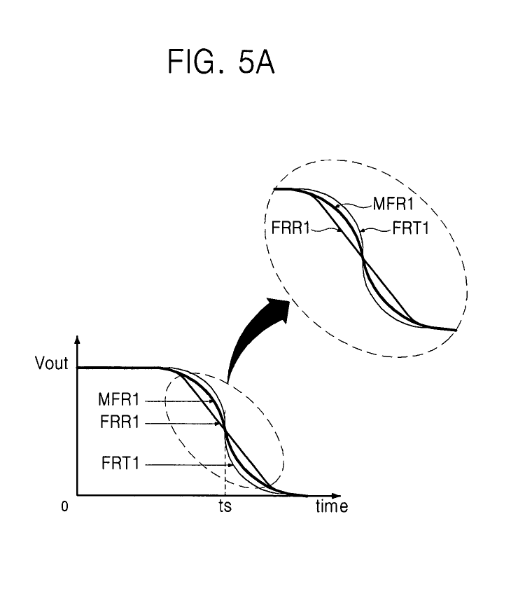

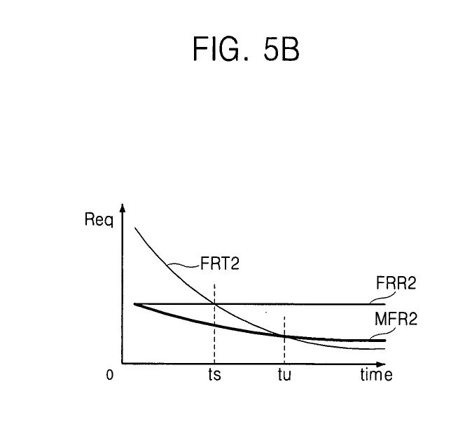

In FIGS. 2A and 2B, a voltage difference between the first node GN (drain terminal) and the second power supply voltage VSS (source terminal) of the second transistor 49 may be decreased due to the presence of the resistor R10 between the first transistor 47 and the second transistor 49. This decrease in the drain-source voltage may increase the reliability of the second transistor 49. However, when the output node FN of the driver circuit 40 is driven to the second power supply voltage VSS, an output voltage Vout may not reach the second power supply voltage VSS rapidly enough after a first time point “ts” as shown in a curve FRR1 illustrated in FIG. 5, and therefore, an output characteristic of the driver circuit 40 may be unstable.

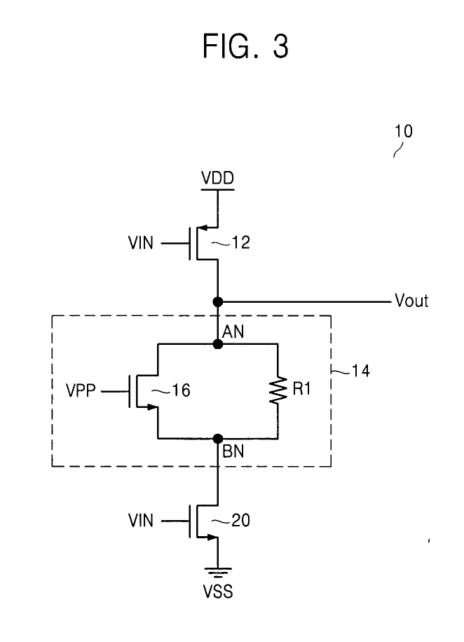

FIG. 3 is a circuit diagram of a driver circuit 10 according to an example embodiment. Referring to FIG. 3, the driver circuit 10, which may be implemented in a volatile memory device such as DRAM or a non-volatile memory device such as read-only memory (ROM), electrically erasable programmable ROM (EEPROM), or flash memory, may drive an output node AN to a first power supply voltage VDD or a second power supply voltage VSS in response to an input signal VIN. The driver circuit 10 may be used in a word line driver circuit or a level shift circuit in a semiconductor memory device. However, an example embodiment is not restricted thereto.

When the driver circuit 10 is used in a word line driver circuit of a semiconductor memory device, the driver circuit 10 may output a driving signal that may drive a corresponding sub-word line of a plurality of sub-word lines in response to a decoded signal (or input signal) received from a word line decoder.

The driver circuit 10 may include a pull-up unit 12, an interface unit 14, and a pull-down unit 20. The pull-up unit 12 may be connected between the first power supply voltage VDD and the output node AN and gated in response to the input signal VIN, thereby forming a current path between the first power supply voltage VDD and the output node AN. The pull-up unit 12 may be implemented by a p-type metal-oxide semiconductor (PMOS) transistor, for example.

The interface unit 14 may be connected between the output node AN and a first node BN and may decrease a voltage of the first node BN in response to a control signal VPP. In detail, the interface unit 14 may decrease the output voltage Vout at the output node AN in response to the control signal VPP that may be enabled during the operation of the driver circuit 10. A voltage level of the control signal VPP may be equal to a level of the first power supply voltage VDD.

The interface unit 14 may include a first transistor 16 and a first resistor R1. The first transistor 16 may be connected between the output node AN and the first node BN and gated in response to the control signal VPP, thereby forming a current path between the output node AN and the first node BN. The first resistor R1 may be connected between the output node AN and the first node BN.

The pull-down unit 20 may be connected between the first node BN and the second power supply voltage VSS and gated in response to the input signal VIN, thereby forming an electrical path between the first node BN and the second power supply voltage VSS. The pull-down unit 20 may be implemented by an n-type metal-oxide semiconductor (NMOS) transistor, for example.

According to another example embodiment, the presence of the first transistor 16 in the interface unit 14 may decrease a voltage difference between the first node BN (drain terminal) and the second power supply voltage VSS (source terminal) of the pull-down unit 20. As a result, the reliability of the pull-down unit 20 may be increased and the pull-down unit 20 may deteriorate gradually.

The driver circuit 10, according to an example embodiment, may prevent degradation of the first transistor 16 and increase the reliability of the pull-down unit 20 due to the presence of the first resistor R1 in the interface unit 14. As such, the performance of driver circuit 10 may be improved as compared to the driver circuits 30 of FIG. 1A and driver circuit 40 of FIG. 2A.

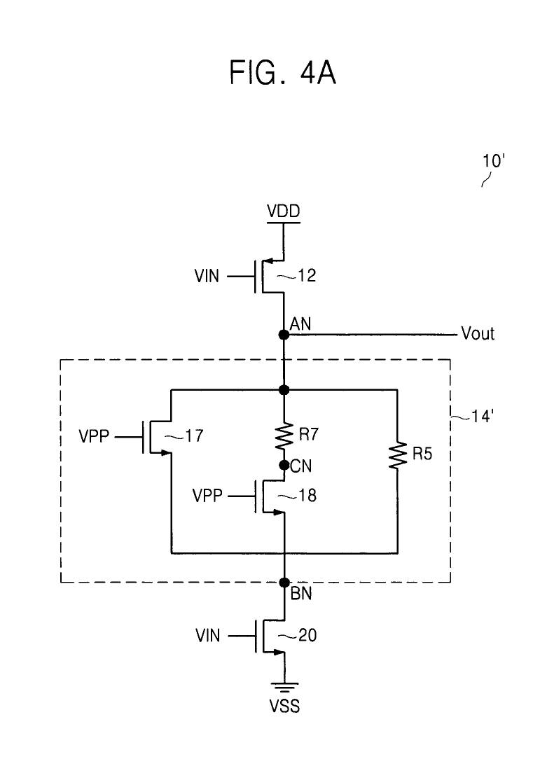

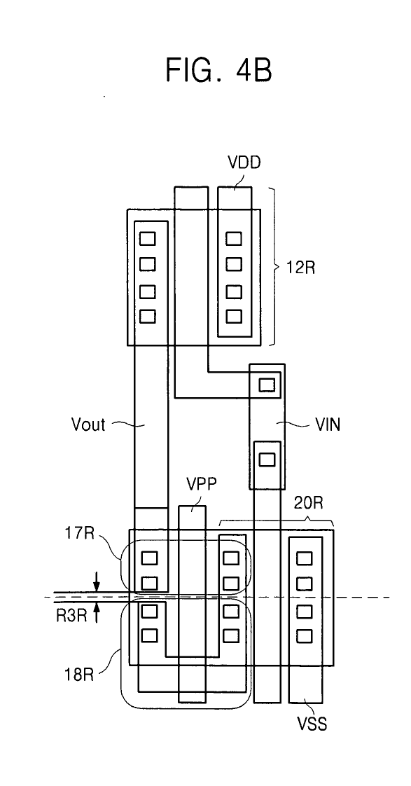

FIGS. 4A and 4B are a circuit diagram and a layout diagram of a driver circuit 10′ according to another example embodiment. Referring to FIG. 3 and FIGS. 4A and 4B, the driver circuit 10′ illustrated in FIG. 4A may include switches somewhat similar to the pull-up unit 12 and the pull-down unit 20 of the driver circuit 10 illustrated in FIG. 3. However, an interface unit 14′ of the driver circuit 10′ may be different from the interface unit 14 of FIG. 3.

The interface unit 14′ may be connected between the output node AN and the first node BN and may decrease the output voltage Vout of the output node AN in response to the control signal VPP. The interface unit 14′ may include a first transistor 17, a first resistor R5, a second resistor R7, and a second transistor 18.

The first transistor 17 may be connected between the output node AN and the first node BN and gated in response to the control signal VPP, thereby forming an electrical path between the output node AN and the first node BN. The voltage level of the control signal VPP may be same as the voltage level of the first power supply voltage VDD. However, an example embodiment is not restricted thereto and different voltage levels may also be employed.

The first resistor R5 may be connected between the output node AN and the first node BN. The second resistor R7 may be connected between the output node AN and a second node CN. The second transistor 18 may be connected between the first node BN and the second node CN and gated in response to the control signal VPP, thereby connecting the first node BN with the second node CN. The channel width and the channel length of the first transistor 17 may be equal to that of the second transistor 18 and the resistance value of the first resistor R5 may be equal to that of the second resistor R7.

The presence of the first transistor 17 and the second transistor 18 in the interface unit 14′ may decrease a voltage difference between the first node BN (drain terminal) and the second power supply voltage VSS (source terminal) of the pull-down unit 20. As a result, the reliability of the pull-down unit 20 may be increased. Additionally, the presence of the first resistor R5 and the second resistor R7 in the interface unit 14′ may prevent degradation of the first transistor 17 and the second transistor 18. This may, in turn, increase the reliability of the pull-down unit 20 resulting in an increase in the performance of the driver circuit 10′.

Referring to FIG. 4B, the pull-up unit 12 may be disposed in a first region 12R and the first transistor 17 may be disposed in a second region 17R. The first resistor R5 and the second resistor R7 may be disposed in a third region R3R. The second transistor 18 may be disposed in a fourth region 18R. The pull-down unit 20 may be disposed in a fifth region 20R. The first resistor R5 and the second resistor R7 may be implemented by a common resistor in the third region R3R in the same third region R3R. Because, the first resistor R5 and the second resistor R7 are implemented by the common resistor, the driver circuit 10′ may have high reliability and high performance while utilizing a relatively smaller area.

Also, since the degradation of the first transistor 17 and the second transistor 18 may be prevented by the presence of the first resistor R5 and the second resistor R7, the driver circuit 10′ may have an improved performance as compared to the driver circuits 30 and 40 of FIGS. 1A and 2A.

FIG. 5A is a graph illustrating the output characteristics of the driver circuits 30, 40, and 10′. FIG. 5B is a graph illustrating equivalent resistance Req of circuit elements connected to the output nodes of the respective driver circuits 30, 40, and 10′.

A curve FRT1 (FIG. 5A) corresponds to the output characteristic of the driver circuit 30 of FIG. 1A and a curve FRT2 (FIG. 5B) corresponds to the equivalent resistance Req of the second transistor 33 connected to the output node DN of the driver circuit 30. As is seen, the equivalent resistance Req of the second transistor 33 (curve FRT2) is greater than an equivalent resistance of resistor R10 (curve FRR2) of FIG. 2A prior to a first time point “ts” and is less than the equivalent resistance of the resistor R10 after the first time point “ts”. Accordingly, as is seen in FIG. 5A, when the output voltage Vout of the driver circuit 30 is driven from the first power supply voltage VDD to the second power supply voltage VSS (e.g., a ground voltage), the output voltage Vout gradually decreases till the first time point “ts” and rapidly drops after the first time point “ts”.

The output characteristic of the driver circuit 40 (FIG. 2A) corresponds to a curve FRR1 of FIG. 5A. As mentioned above, the equivalent resistance Req of the resistor R10 (FIG. 2A) corresponds to the curve FRR2 and, as is seen, has a constant value. As is seen in FIG. 5A, when the output voltage Vout of the driver circuit 40 (curve FRR1) is driven from the first power supply voltage VDD to the second power supply voltage VSS (e.g., a ground voltage), the output voltage Vout rapidly decreases till the first time point “ts” and decreases gradually thereafter, due to tail current of the second transistor 49.

The output characteristic of the driver circuit 10′ corresponds to a curve MFR1 and the equivalent resistance Req of the interface unit 14′ connected to the output node AN (FIG. 3) corresponds to a curve MFR2. As is seen, the equivalent resistance Req of the interface unit 14′ (curve MFR2) is less than the equivalent resistance Req of the second transistor 33 (curve FRT2) prior to a second time point “tu” and greater thereafter.

Additionally, the equivalent resistance Req of the interface unit 14′ (curve MFR2) is less than the equivalent resistance Req of the resistor R10 (curve FRR2). Therefore, when the output voltage Vout of the driver circuit 10′ is driven from the first power supply voltage VDD to the second power supply voltage VSS (e.g., a ground voltage), the output voltage Vout drops at a relatively faster rate than the output voltage Vout of the driver circuit 30 (curve FRT1) of FIG. 1A till the first time point “ts” and thereafter drops at a faster rate than the output voltage Vout of the driver circuit 40 (curve FRR1) of FIG. 2A.

As such, the performance of driver circuit 10′ may be assumed to be a combination of the performances of driver circuit 30 (FIG. 1A) and the driver circuit 40 (FIG. 2A). Accordingly, driver circuit 10′ may solve both a reliability problem that may occur with a transistor of driver circuit 30 (FIG. 1A) and a performance problem that may occur with driver circuit 40 (FIG. 2A).

FIG. 6 is a block diagram of a semiconductor memory device 100 according to an example embodiment. Referring to FIGS. 3, 4A, and 6, the semiconductor memory device 100 may include first through fourth memory bank units 110, 120, 130, and 140 and a peripheral circuit 150. The semiconductor memory device 100 may be a volatile memory device, such as DRAM, and each of the first through fourth memory bank units 110, 120, 130, and 140 may respectively include a memory bank 112, 122, 132, and 142, a row decoding block 114, 124, 134, and 144, a sub-word line driver 115 (shown only in first memory bank unit 110 for sake of brevity, but respective sub-word line drivers are also present in second through fourth memory bank units 120, 130 and 140), and a column decoding block 116, 126, 136, or 146.

Hereafter, the structure and working of the memory bank units 110, 120, 130, and 140 is described with respect to memory bank unit 110. However, it will be apparent to one of ordinary skill that memory bank units 120, 130 and 140 may have a similar structure and, as such, the details thereof are omitted for the sake of brevity. The first memory bank unit 110 may include the memory bank 112, the row decoding block 114, the sub-word line driver 115, and the column decoding block 116. The memory bank 112 may include at least one memory cell C1 which stores data. The row decoding block 114 may receive and decode a row address signal (now shown) output from the peripheral circuit 150 and may activate a corresponding row line (e.g., Nweib) among a plurality of row lines. The row decoding block 114 may include a row driver 114-1 and a row decoder 114-2.

The row driver 114-1 of the row decoding block 114 may activate the corresponding row line (e.g., Nweib) among the plurality of row lines in response to a decoded row address signal (not shown) output from the row decoder 114-2. The row line may be referred to as a word line, and may be a normal word line or a redundancy word line. The row driver 114-1 may be implemented by the driver circuit 10 or 10′ described in detail above with reference to FIGS. 3 or 4A. Accordingly, the description thereof is omitted for the sake of brevity. The row decoder 114-2 may receive and decode the row address signal output from the peripheral circuit 150 and output the decoded row address signal.

The sub-word line driver 115 may activate a corresponding sub-word line SWL among a plurality of sub-word lines in response to a signal received through the row line (e.g., Nweib) activated by the row decoder 114-2. The column decoding block 116 may receive and decode a column address signal (not shown) output from the peripheral circuit 150 and activate a corresponding column line (e.g., CSL) among a plurality of column lines. As such, the peripheral circuit 150 may output a row address signal (not shown) and a column address signal (not shown) to select the first memory cell C1 of memory bank 112.

Example embodiments having thus been described, it will be obvious that the same may be varied in many ways. Such variations are not to be regarded as a departure from the intended spirit and scope of example embodiments, and all such modifications as would be obvious to one skilled in the art are intended to be included within the scope of the following claims.

What is claimed is:

1. A driver circuit comprising:
a pull-up unit configured to connect an output node to a first power supply voltage in response to an input signal;
an interface unit connected between the output node and a first node to decrease a voltage of the output node in response to a control signal; and
a pull-down unit configured to connect the first node with a second power supply voltage,
wherein the interface unit includes,
a first transistor configured to connect the output node with the first node in response to the control signal; and
a first resistor connected between the output node and the first node.

2. The driver circuit of claim 1, wherein a voltage level of the control signal is equal to a level of the first power supply voltage.

3. The driver circuit of claim 1, wherein the pull-up unit is a p-type metal-oxide semiconductor (PMOS) transistor and the pull-down unit is an n-type metal-oxide semiconductor (NMOS) transistor.

4. The driver circuit of claim 1, wherein the interface unit further includes a second resistor and a second transistor connected in series between the output node and the first node.

5. The driver circuit of claim 4, wherein a channel width and a channel length of the first transistor are respectively the same as those of the second transistor.

6. The driver circuit of claim 4, wherein a resistance value of the first resistor is the same as that of the second resistor.

7. The driver circuit of claim 1, wherein the driver circuit is used for a word line driver circuit of a semiconductor memory device.

8. The driver circuit of claim 4, wherein the first resistor and the second resistor are implemented by a common resistor in a layout of the driver circuit.

9. A semiconductor memory device comprising:
a row decoder configured to receive and decode a row address signal and to output a decoded row address signal;
a row driver configured to activate a corresponding word line among a plurality of word lines in response to the decoded row address signal, the corresponding word line connected to an output node of the row driver; and
a sub-word line driver configured to activate a corresponding sub-word line from a plurality of sub-word lines in response to a signal input from the activated word line,
wherein the row driver includes,
a pull-up unit configured to connect an output node to a first power supply voltage in response to the decoded row address signal;
an interface unit connected between the output node and a first node to decrease a voltage of the output node in response to a control signal; and
a pull-down unit configured to connect the first node with a second power supply voltage, and
wherein the interface unit includes,
a first transistor configured to connect the output node with the first node in response to the control signal; and
a first resistor connected between the output node and the first node.

10. The semiconductor memory device of claim 9, wherein a voltage level of the control signal is equal to a level of the first power supply voltage.

11. The semiconductor memory device of claim 9, wherein the pull-up unit is a p-type metal-oxide semiconductor (PMOS) transistor and the pull-down unit is an n-type metal-oxide semiconductor (NMOS) transistor.

12. The semiconductor memory device of claim 9, wherein the interface unit further includes a second resistor and a second transistor connected in series between the output node and the first node.

13. The semiconductor memory device claim 12, wherein a channel width and a channel length of the first transistor are respectively the same as those of the second transistor.

14. The semiconductor memory device of claim 12, wherein a resistance value of the first resistor is the same as that of the second resistor.

15. The semiconductor memory device of claim 12, wherein the first resistor and the second resistor are implemented by a common resistor in a layout of the row driver.
